(19) United States
(12) Patent Application Publication
(10) Pub. No.: US 2026/0156776 A1
(43) Pub. Date: Jun. 4, 2026

(54) Liquid Cooled Faceplate for Cooling High Power Pluggable Optical Modules and Other Devices

(71) Applicant: Ciena Corporation, Hanover, MD (US)

(72) Inventors: Peter Ajersch, Ottawa (CA); Trevor Meunier, Kemptville (CA)

(21) Appl. No.: 18/966,393

(22) Filed: Dec. 3, 2024

(51) Int. Cl. H05K 7/20

(52) U.S. Cl. CPC H05K 7/20272; H05K 7/20254; H05K 7/20263

(57) ABSTRACT

A liquid cooled faceplate assembly for cooling a pluggable optical module including a faceplate body and a coolant channel coupled to a surface of the faceplate body or formed through the faceplate body adjacent to a nose of the pluggable optical module when the pluggable optical module is inserted through an opening formed in the faceplate body and thermally coupled to the faceplate body. The liquid cooled faceplate assembly also includes a bullnose including a wall structure integrally formed with or coupled to the surface or another surface of the faceplate body and disposed adjacent and thermally coupled to a side of the nose of the pluggable optical module when the pluggable optical module is inserted through the opening formed in the faceplate body.

### TECHNICAL FIELD

The present disclosure relates generally to the telecommunications and data networking fields. More particularly, the present disclosure relates to a liquid cooled faceplate for cooling high power pluggable optical modules (POMs) and other devices, as well as an associated network module or element and method.

### BACKGROUND

POMs are widely used in telecommunications and data networking equipment. Over time, POM performance has dramatically increased, but with a penalty in power consumption and associated cooling challenges, as shown in FIG. 1. The industry is presently at a junction where air cooling a cutting edge POM is costly, and in some cases simply not possible. An example of such an issue is the inability to cool a 400ZR/400ZR+ or 800ZR plug in a 200G/400G system with air, which may require a 400ZR/400ZR+ or 800ZR plug to be dropped from the feature set of a future networking product.

Cooling a POM via liquid cooling by means of a riding liquid cooled cold plate over the case top of the POM serves to extend the maximum coolable POM power to approximately 40-50 W. The total cooled power is dependent on many factors, including the internal construction of the POM, the coolant supply temperature, the quality of the thermal interfaces, the coolant flow rate, etc.

Cooling a POM via integrated liquid cooling of the case top of the POM extends the maximum power capability to approximately 90 W, however such a POM may not be MSA compliant and desirable production cost targets may be difficult to achieve.

Thus, it is desirable to extend the coolable POM power without adding significant cost to the system.

The system limiting temperatures of a POM sometimes occur in the nose of the POM, which is considered to be the portion of the POM that protrudes forward of the faceplate boundary of the system. It should be noted that the system limiting temperatures occur in different parts of the POM depending on the internal construction of the POM and the system integration. For a 400ZR/400ZR+ or 800ZR plug cooled by a liquid cooled riding cold plate over the case top, the digital signal processor (DSP), driver, modulator, and integrated coherent receiver (ICR) are well cooled, as they are disposed proximate to the riding cold plate. However, the integrable tunable laser assembly (ITLA), which is typically located in the nose of the POM, is not well cooled, as the thermal path between the ITLA and the environment (either air or coolant) is more circuitous and more resistant.

The present background is provided as environmental context only. It will be readily apparent to those of ordinary skill in the art that the principles and concepts of the present disclosure may be implemented in other environmental contexts equally, without limitation.

### SUMMARY

The present disclosure serves to remove heat from the nose of a POM through a more direct path than is otherwise available. In doing so, the total power dissipated by the DSP, ITLA, and other components is a significantly higher value. Thus, the trend of increasingly higher performing MSA compliant POMs can continue on its trajectory, well beyond 50 W, while providing a practical thermal solution.

The faceplate of a telecommunications or data networking module or element (blade) is liquid cooled for the purpose of providing a cold sink for the adjacent heat sources. One such adjacent heat source is a POM, such as QSFP-DD, in particular the nose of the POM. A thermal bridge between the nose of the POM and the faceplate is provided by using a thermally conductive elastic material, such as graphite-over-foam (GOF), between one or more surfaces of the nose and one or more surfaces created by one or more bullnoses that extend from the primary surface of the faceplate.

The faceplate is liquid cooled by tying it in to the liquid cooled sub-system of the blade. The coolant path through the faceplate is a coolant channel, such as a copper pipe or the like, that is thermally coupled to the wall of the faceplate adjacent to the nose of the POM. The thermal coupling of the copper pipe with the faceplate is done by means such as brazing a circular cross-section pipe into a circular cross-section channel cut into the faceplate, for example. Other bonding methods are possible, including epoxy bonding and soldering, for example. Other cross-sections of pipe and matching cut channel are also possible, including square and “D”, for example. The interior of the coolant channel may include fins, protrusions, or other heat transfer enhancements to improve the convective heat transfer between the heated surfaces and the coolant. Further, the coolant channel may be constructed without brazing or bonding; i.e. by boring a long hole through the faceplate. The key aspect of the coolant channel is that a practical flow rate of coolant passes through the body of the faceplate to take heat away from the faceplate and the adjacent noses of the POMs.

There is an inlet and an outlet to the coolant channel adjacent to the faceplate. These serve to connect the coolant channel to the liquid cooling sub-system of the blade. The inlet and outlet may be constructed as beaded tube ends, for example.

The bullnoses that extend forward of the faceplate and all the material between the GOF bridges and the coolant channel has good thermal conductivity and ample cross-section, such that the thermal resistance between the GOF and the coolant channel is low. Thermal resistance R=L/kA, where L is the length of heat travel, k is material conductivity, and A is the cross-section through which the heat travels. The present disclosure aims for small R, which is readily achieved when using copper, aluminum, or similar materials for the faceplate and bullnoses, while easily avoiding bullnose geometry with a large L/A ratio. The bullnoses are also constructed so that they provide a solid very low deflection backstop for the GOF, which will be under compressive forces when the associated POM is installed.

A variant of the present disclosure includes a faceplate bullnose that is itself liquid cooled. This is accomplished by creating a coolant channel in the bullnose and tying it in to the liquid cooled sub-system of the blade via the coolant channel of the faceplate. The value of this variant is to bring the cold sink even closer to the GOF (or other arrangement) adjacent to the POM nose, in effect eliminating the thermal penalty that would otherwise be present between the bullnose and the main faceplate.

In some embodiments, the present disclosure provides a liquid cooled faceplate assembly for cooling a pluggable optical module including a faceplate body and a coolant channel coupled to a surface of the faceplate body or formed through the faceplate body adjacent to a nose of the pluggable optical module when the pluggable optical module is inserted through an opening formed in the faceplate body and thermally coupled to the faceplate body. The liquid cooled faceplate assembly also includes a bullnose including a wall structure integrally formed with or coupled to the surface or another surface of the faceplate body and disposed adjacent and thermally coupled to a side of the nose of the pluggable optical module when the pluggable optical module is inserted through the opening formed in the faceplate body. In some embodiments, the wall structure defines a bullnose coolant channel that is fluidly coupled to the coolant channel. In some embodiments, the bullnose further includes a graphite-over-foam pad coupled to the wall structure and adapted to thermally couple the bullnose to the side of the nose of the pluggable optical module. The coolant channel includes a coolant inlet and a coolant outlet adapted to be fluidly coupled to a liquid cooling system of a network module or element. In some embodiments, the coolant channel includes or defines internal fins or protrusions acting as internal heat transfer features. In some embodiments, the coolant channel includes an upper coolant channel coupled to the surface of the faceplate body or formed through the faceplate body adjacent to noses of a row of upper pluggable optical modules when the upper pluggable optical modules are inserted through an upper row of openings formed in the faceplate body and thermally coupled to the faceplate body and a lower coolant channel coupled to the surface of the faceplate body or formed through the faceplate body adjacent to noses of a row of lower pluggable optical modules when the lower pluggable optical modules are inserted through a lower row of openings formed in the faceplate body and thermally coupled to the faceplate body. In some embodiments, the bullnose includes a plurality of bullnoses each including the wall structure integrally formed with or coupled to the surface or the other surface of the faceplate body and disposed adjacent and thermally coupled to sides of noses of a row of pluggable optical modules when the pluggable optical modules are inserted through a row of openings formed in the faceplate body. In some embodiments, the coolant channel is disposed between the nose of the pluggable optical module and a cold plate disposed adjacent and thermally coupled to a body of the pluggable optical module when the pluggable optical module is inserted through the opening formed in the faceplate body, where the cold plate is disposed within a housing to which the faceplate body is attached.

In some embodiments, the present disclosure provides a network element including a housing, a pluggable optical module having a body disposed within the housing and a nose extending from the housing, and a liquid cooled faceplate assembly for cooling the pluggable optical module including a faceplate body and a coolant channel coupled to a surface of the faceplate body or formed through the faceplate body adjacent to the nose of the pluggable optical module when the pluggable optical module is inserted through an opening formed in the faceplate body and thermally coupled to the faceplate body. The liquid cooled faceplate assembly also includes a bullnose including a wall structure integrally formed with or coupled to the surface or another surface of the faceplate body and disposed adjacent and thermally coupled to a side of the nose of the pluggable optical module when the pluggable optical module is inserted through the opening formed in the faceplate body. In some embodiments, the wall structure defines a bullnose coolant channel that is fluidly coupled to the coolant channel. In some embodiments, the bullnose further includes a graphite-over-foam pad coupled to the wall structure and adapted to thermally couple the bullnose to the side of the nose of the pluggable optical module. The coolant channel includes a coolant inlet and a coolant outlet adapted to be fluidly coupled to a liquid cooling system of a network module or element. In some embodiments, the coolant channel includes or defines internal fins or protrusions acting as internal heat transfer features. In some embodiments, the pluggable optical module includes a row of upper pluggable optical modules and a row of lower pluggable optical modules, and the coolant channel includes an upper coolant channel coupled to the surface of the faceplate body or formed through the faceplate body adjacent to noses of the row of upper pluggable optical modules when the upper pluggable optical modules are inserted through an upper row of openings formed in the faceplate body and thermally coupled to the faceplate body and a lower coolant channel coupled to the surface of the faceplate body or formed through the faceplate body adjacent to noses of the row of lower pluggable optical modules when the lower pluggable optical modules are inserted through a lower row of openings formed in the faceplate body and thermally coupled to the faceplate body. In some embodiments, the pluggable optical module includes a row of pluggable optical modules, and the bullnose includes a plurality of bullnoses each including the wall structure integrally formed with or coupled to the surface or the other surface of the faceplate body and disposed adjacent and thermally coupled to sides of noses of a row of pluggable optical modules when the pluggable optical modules are inserted through a row of openings formed in the faceplate body. In some embodiments, the coolant channel is disposed between the nose of the pluggable optical module and a cold plate disposed adjacent and thermally coupled to a body of the pluggable optical module when the pluggable optical module is inserted through the opening formed in the faceplate body, where the cold plate is disposed within the housing to which the faceplate body is attached.

In some embodiments, the present disclosure provides a faceplate liquid cooling method for cooling a pluggable optical module including delivering a coolant flow to a faceplate of a network module or element adjacent to a nose of a pluggable optical module thermally coupled to the faceplate, where the coolant flow is provided through a coolant channel coupled to a surface of the faceplate or formed through a body of the faceplate. In some embodiments, the faceplate liquid cooling method also includes delivering the coolant flow to a bullnose integrally formed with or coupled to the surface or another surface of the faceplate and disposed adjacent and thermally coupled to a side of the nose of the pluggable optical module.

In some embodiments, the present disclosure provides a liquid cooled faceplate assembly for cooling a device including a faceplate body, a coolant channel coupled to a surface of the faceplate body or formed through the faceplate body adjacent to the device when the device is disposed adjacent to the faceplate body and thermally coupled to the faceplate body, and a bullnose including a wall structure integrally formed with or coupled to the surface or another surface of the faceplate body and disposed adjacent and thermally coupled to a side of the device when the device is disposed adjacent to the faceplate body. In some embodiments, the wall structure defines a bullnose coolant channel that is fluidly coupled to the coolant channel. In some embodiments, the bullnose further includes a graphite-over-foam pad coupled to the wall structure and adapted to thermally couple the bullnose to the side of the device.

It will be readily apparent to those of ordinary skill in the art that aspects and features of each of the described embodiments may be incorporated, omitted, and/or combined as desired in a given application, without limitation.

### BRIEF DESCRIPTION OF THE DRAWINGS

The present disclosure is illustrated and described with reference to the various drawings, in which like reference numbers are used to denote like assembly components/method steps, as appropriate, and in which:

FIG. 1 is a chart illustrating the increase in POM performance over time, with an associated increase in power consumption and cooling challenges over time;

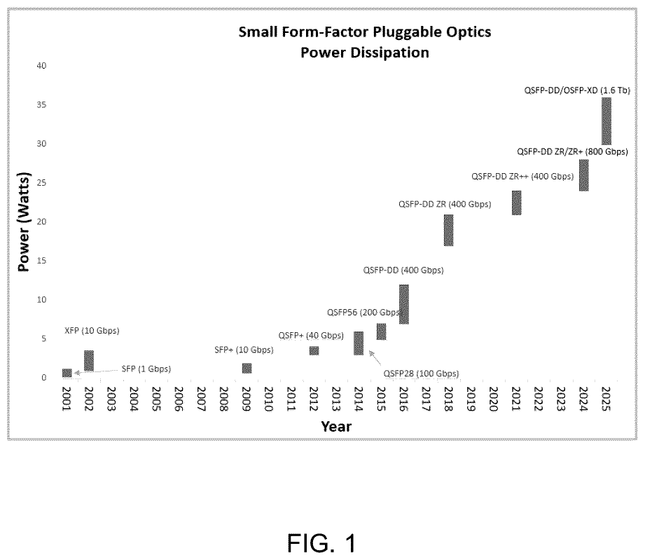

FIG. 2 is a front perspective view of one embodiment of the network element or module of the present disclosure, incorporating one embodiment of the liquid cooled faceplate of the present disclosure;

FIG. 3 is a rear perspective view of one embodiment of the network element or module of the present disclosure, incorporating one embodiment of the liquid cooled faceplate of the present disclosure;

FIG. 4 is a rear perspective view of one embodiment of the liquid cooled faceplate of the present disclosure;

FIG. 5 is a front perspective view of one embodiment of the liquid cooled faceplate of the present disclosure;

FIG. 6 is a cross-sectional plan view of one embodiment of the liquid cooled faceplate of the present disclosure;

FIG. 7 is a partial expanded cross-sectional plan view of one embodiment of the liquid cooled faceplate of the present disclosure;

FIG. 8 is a cross-sectional end view of one embodiment of the liquid cooled faceplate of the present disclosure;

FIG. 9 is a schematic view of another embodiment of the liquid cooled faceplate of the present disclosure, incorporating a liquid cooled bullnose;

FIG. 10 is a perspective view of a POM model of the present disclosure;

FIG. 11 is cross-sectional end and plan views of the POM model of the present disclosure as cooled by the one embodiment of the liquid cooled faceplate of the present disclosure;

FIG. 12 is a table detailing components of several POM models of the present disclosure as cooled by the one embodiment of the liquid cooled faceplate of the present disclosure; and

FIG. 13 is a flowchart of one embodiment of the liquid cooled faceplate method of the present disclosure.

It will be readily apparent to those of ordinary skill in the art that aspects and features of each of the illustrated embodiments may be incorporated, omitted, and/or combined as desired in a given application, without limitation.

### DETAILED DESCRIPTION

Again, the present disclosure serves to remove heat from the nose of a POM through a more direct path than is otherwise available. In doing so, the total power dissipated by the DSP, ITLA, and other components is a significantly higher value. Thus, the trend of increasingly higher performing MSA compliant POMs can continue on its trajectory, well beyond 50 W, while providing a practical thermal solution.

The faceplate of a telecommunications or data networking module or element (blade) is liquid cooled for the purpose of providing a cold sink for the adjacent heat sources. One such adjacent heat source is a POM, in particular the nose of the POM. A thermal bridge between the nose of the POM and the faceplate is provided by using a thermally conductive elastic material, such as GOF, between one or more surfaces of the nose and one or more surfaces created by one or more bullnoses that extend from the primary surface of the faceplate.

The faceplate is liquid cooled by tying it in to the liquid cooled sub-system of the blade. The coolant path through the faceplate is a coolant channel, such as a copper pipe or the like, that is thermally coupled to the wall of the faceplate adjacent to the nose of the POM. The thermal coupling of the copper pipe with the faceplate is done by means such as brazing a circular cross-section pipe into a circular cross-section channel cut into the faceplate, for example. Other bonding methods are possible, including epoxy bonding and soldering, for example. Other cross-sections of pipe and matching cut channel are also possible, including square and “D”, for example. The interior of the coolant channel may include fins, protrusions, or other heat transfer enhancements to improve the convective heat transfer between the heated surfaces and the coolant. Further, the coolant channel may be constructed without brazing or bonding; i.e. by boring a long hole through the faceplate. The key aspect of the coolant channel is that a practical flow rate of coolant passes through the body of the faceplate to take heat away from the faceplate and the adjacent noses of the POMs.

There is an inlet and an outlet to the coolant channel adjacent to the faceplate. These serve to connect the coolant channel to the liquid cooling sub-system of the blade. The inlet and outlet may be constructed as beaded tube ends, for example.

The bullnoses that extend forward of the faceplate and all the material between the GOF bridges and the coolant channel has good thermal conductivity and ample cross-section, such that the thermal resistance between the GOF and the coolant channel is low. Thermal resistance R=L/kA, where L is the length of heat travel, k is material conductivity, and A is the cross-section through which the heat travels. The present disclosure aims for small L and large k and A. The bullnoses are also constructed so that they provide a solid very low deflection backstop for the GOF, which will be under compressive forces when the associated POM is installed.

A variant of the present disclosure includes a faceplate bullnose that is itself liquid cooled. This is accomplished by creating a coolant channel in the bullnose and tying it in to the liquid cooled sub-system of the blade via the coolant channel of the faceplate. The value of this variant is to bring the cold sink even closer to the GOF (or other arrangement) adjacent to the POM nose, in effect eliminating the thermal penalty that would otherwise be present between the bullnose and the main faceplate.

With the faceplate assembly constructed as described in the present disclosure, heat generated in the nose of the POM is conducted through the material and surfaces of the nose though the thermal conductive elastic interface (GOF, for example) to the bullnose(s) on the liquid cooled faceplate, where it is ultimately dissipated into the coolant. This thermal path is, in effect, a path dedicated for the nose of the POM. By dividing the primary coolant paths from the POM into two parts, namely 1) the case top cold plate and 2) the nose path to the liquid cooled faceplate, the temperatures of all components in the POM benefit. The benefit to the system limiting components in the nose is significant because what is of key importance here as compared to other methods (including known GOF methods) is that the temperature of the cold sink (bullnose extensions of the liquid cooled faceplate) can be very low as compared to what can be achieved in a similar air cooled design (it can even be cooler than ambient air). Therefore, the effectiveness of the nose cooling is superior.

The concept of the present disclosure is easily extended from cooling a single POM to cooling two belly-to-belly mounted POMs, and further to multiple such POMs in a row. The concept is readily extended to an array of 16 top side POMs and 16 bottom side POMs on a 1 U server blade, for a total of 32 high power coherent POMs in a 1 U box. In a 1 U horizontal “pizza box” blade, the features used to cool the faceplate and the POM noses are sufficiently small in height to still allow for air inlets in the faceplate above the upper POM and below the lower POM, thus allowing for a hybrid liquid-air cooled system. In a full implementation, the system might cool on the order of 2 kW of POMs via the liquid cooled faceplate, additional power from motherboard components cooled via the liquid cooled faceplate, kWs of power from central processing units (CPUs), application specific integrated circuits (ASICs), field programmable gate arrays (FPGAs), etc. via device specific liquid cooled cold plates, and additional power from air cooled devices.

With cooling being by liquid or by hybrid liquid-air, the facility operating cost of cooling (cooling the room) is expected to very low (low PUE). Furthermore, system acoustics are expected to be very good (low dB-A) because the fan speed requirement for the POMs and other liquid cooled devices is basically nil.

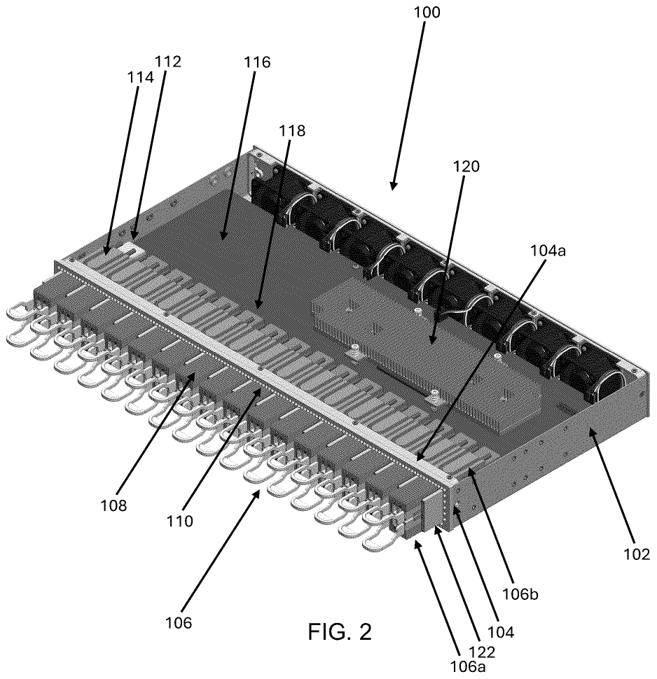

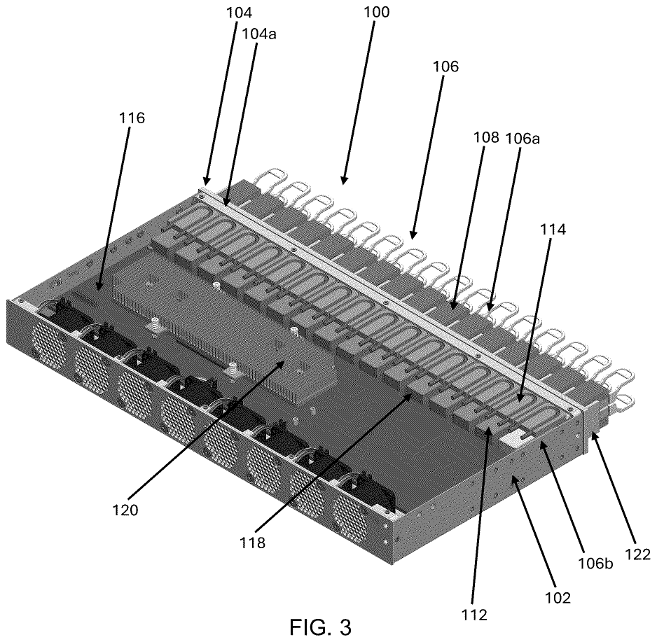

Referring to FIGS. 2 and 3, in one embodiment, the network module or element 100 of the present disclosure includes a housing 102 that houses the components of the module or element 100. A faceplate 104 including a faceplate body 104a is disposed at the front of the housing 102 and is configured to receive one or more POMs 106, such that the one or more POMs 106 can make connections with the components of the module or element 100 through the faceplate 104. It should be noted that “faceplate” and “faceplate body” are used interchangeably. As mentioned above, the nose 106a of each of the POMs 106 is the portion of each of the POMs 106 protruding from the faceplate 104 external to the housing 102, while the body 106b of each of the POMs 106 is the portion of each of the POMs 106 disposed within the housing 102. The POMs 106 may be air cooled via a cooling air flow through the faceplate 104. Accordingly, a heatsink 108 may be disposed/coupled adjacent to the nose 106a of each of the POMs external to the faceplate 104 and air flow ports 110 may be formed through the faceplate 104 above, below, and/or adjacent to the rows of POMs 106. The POMs 106 may also be liquid cooled via liquid cooling system 112 disposed within the housing 102, consisting of a coolant supply and removal lines provided in the housing 102 that serve to supply coolant to and remove coolant from the module or element 100. A cold plate 114 may be disposed/coupled adjacent to the body 106b of each of the POMs 106 within the housing 102. Each of these cold plates 114 is coupled to the liquid cooling system 112 of the housing 102. Thus, the module or element 100 may be provided with air cooling, liquid cooling, or hybrid liquid-air cooling as desired. Although not central to the present disclosure, a printed circuit board (PCB) 116 is enclosed within the housing 102 on which cages 118 for the POMs 106 are disposed, as well as the other components of the module or element 100. Dedicated heatsinks 120 may be provided for some or all of these components within the housing 102.

Bullnoses 122 protrude forward from the external surface of the faceplate 104, between which the POMs 106 are disposed. These bullnoses 122 may be coupled to or integrally formed with the external surface of the faceplate 104 and serve to thermally contact the nose 106a of each of the POMs 106 and thermally couple each of the POMs 106 to the faceplate 104. Thus, an efficient thermal path is provided between the nose 106a of each of the POMs 106, the bullnoses 122, and the faceplate 102, as is described in greater detail below.

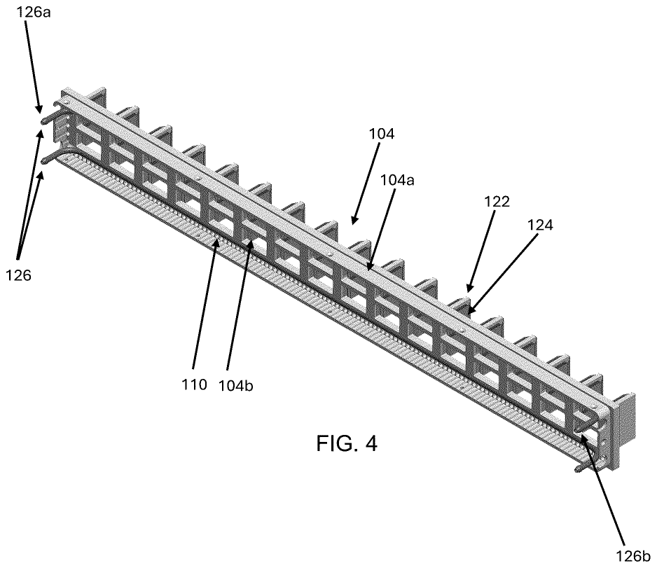

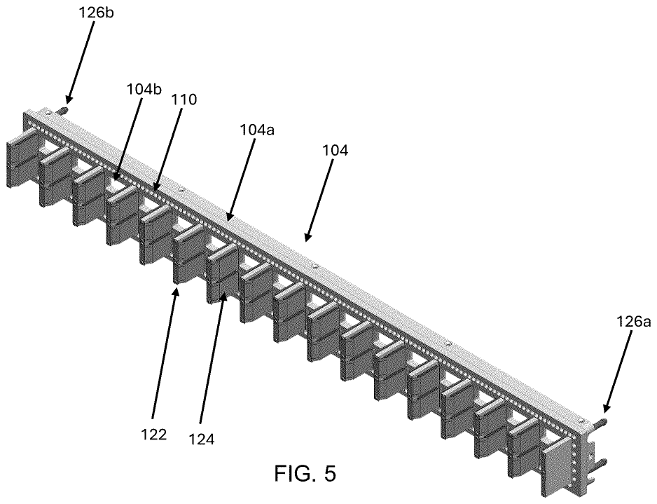

Referring to FIGS. 4 and 5, in one embodiment, the faceplate 104 includes a plurality of openings 104b through which the POMs 106 are inserted and the plurality of air flow ports 110 enabling air flow through the faceplate 104. The bullnoses 122 protrude forward from the external surface of the faceplate 104 and thermally contact the inserted POMs 106, optionally through the GOF pads 124 or other deflectable thermal contact surfaces disposed on the side surfaces of each of the bullnoses 122. In this manner, the bullnoses 122 form bays that extend from external surface of the faceplate 104 through which the POMs 106 are inserted into the faceplate 104, with each bay engaging the nose 106a of the associated POM 106 and thermally coupling the nose 106a of the POM 106 to the faceplate 104.

The faceplate 104 is liquid cooled by tying it in to the liquid cooling system 112 of the module or element 100. The coolant path through the faceplate 104 is one or more coolant channels 126, such as a copper pipe or the like, that is thermally coupled to the internal wall of the faceplate body 104a adjacent to the noses 106a of the POMs 106. The thermal coupling of the copper pipe with the faceplate 104 is done by means such as brazing a circular cross-section pipe into a circular cross-section channel cut into the internal wall of the faceplate 104, for example. Other bonding methods are possible, including epoxy bonding and soldering, for example. Other cross-sections of pipe and matching cut channel are also possible, including square and “D”, for example. As illustrated, multiple coolant channels 126 may be provided in the faceplate 104, such as an upper coolant channel 126 for cooling the faceplate 104 adjacent to an upper row of POMs 106 and a lower coolant channel 126 for cooling the faceplate 104 adjacent to a lower row of POMs 106. Alternatively or in addition, a single coolant channel 126 may be provided between the upper row of POMs 106 and the lower row of POMs 106. Each of these coolant channels 126 may be straight, or may traverse a circuitous path through the faceplate 104. The interior of each of the coolant channels 126 may include fins, protrusions, or other heat transfer enhancements to improve the convective heat transfer between the heated surfaces and the coolant. Further, each of the coolant channels 126 may be constructed without brazing or bonding; i.e. by boring long holes through the faceplate body 104a. The key aspect of the coolant channel 126 is that a practical flow rate of coolant passes through the body of the faceplate 104 to take heat away from the faceplate 104 and the adjacent noses 106a of the POMs 106. Further, each of the coolant channels 126 may be provided with external fins, protrusions, or other external surface area enhancing features that serve to cool the air flow passing through the faceplate 104 and by the coolant channels 126 into the housing 102.

There is an inlet 126a and an outlet 126b to each of the coolant channels 126 adjacent to the faceplate 104. These serve to connect the coolant channels 126 to the liquid cooling system 112. The inlet 126a and outlet 126b may be constructed as beaded tube ends, for example.

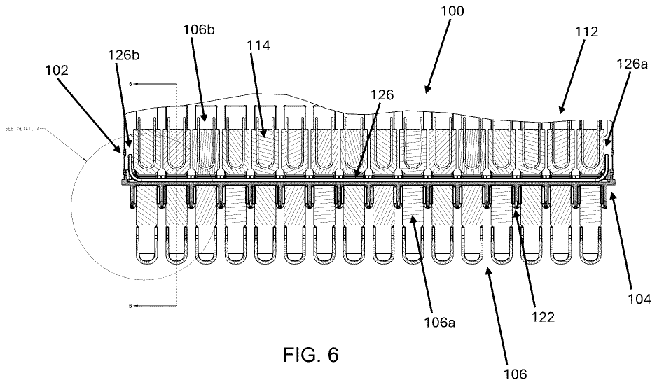

Referring to FIG. 6, the location of the coolant channels 126 is shown in more detail. Each of the coolant channels 126 runs adjacent to the internal surface of the faceplate 104, or through the faceplate 104, from the inlet 126a to the outlet 126b between the noses 106a of the associated POMs 106 and the associated cold plates 114 disposed in the housing 102. Both the coolant channels 126 and the cold plates 114 are coupled to the liquid cooling system 112 of the module or element 100, the coolant channels 126 circulating coolant to the faceplate 104, bullnoses 122, and the noses 106a of the POMs 106 and the cold plates 114 circulating coolant to the bodies 106b of the POMs 106.

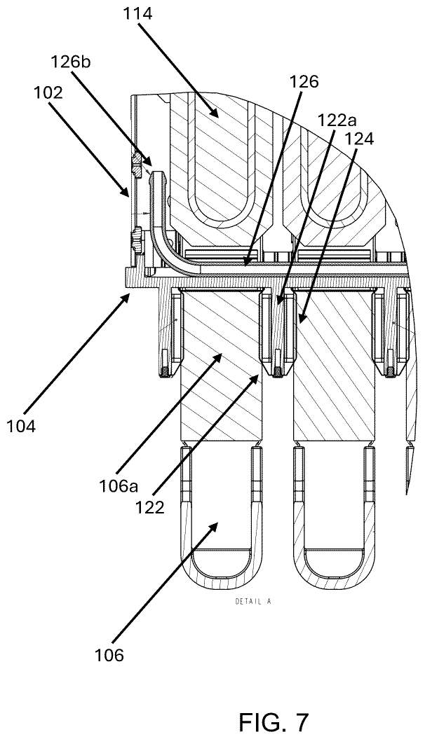

Referring to FIG. 7, the configuration of the bullnoses 122 is shown in more detail. Again, each of the coolant channels 126 runs adjacent to the internal surface of the faceplate 104, or through the faceplate 104, from the inlet 126a to the outlet 126b between the noses 106a of the associated POMs 106 and the associated cold plates 114 disposed in the housing 102. Both the coolant channels 126 and the cold plates 114 are coupled to the liquid cooling system 112 of the module or element 100, the coolant channels 126 circulating cooling to the faceplate 104, bullnoses 122, and the noses 106a of the POMs 106 and the cold plates 114 circulating coolant to the bodies 106b of the POMs 106. Each of the bullnoses 122 includes a wall structure 122a made of a high conductivity metallic material or the like that is integrally formed with or is coupled to and protrudes from the external surface of the faceplate 104. The GOF pads 124 that thermally contact the sides of the noses 106a of the POMs 106 are coupled to the sides of the wall structure 122a. It should be noted that the function GOF pads 124 can alternatively be accomplished by other appropriate thermal interfaces (elastic, gel, putty, etc.).

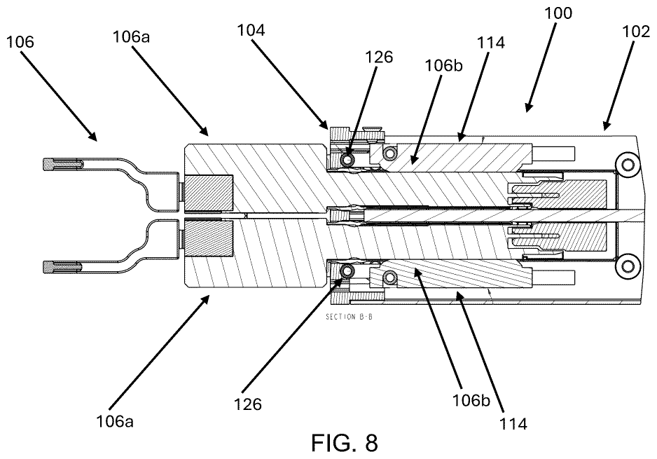

Referring to FIG. 8, the location of the coolant channels 126 is again shown in more detail. Each of the coolant channels 126 runs adjacent to the internal surface of the faceplate 104, or through the faceplate 104, from the inlet 126a to the outlet 126b between the noses 106a of the associated POMs 106 and the associated cold plates 114 disposed in the housing 102. Both the coolant channels 126 and the cold plates 114 are coupled to the liquid cooling system 112 of the module or element 100, the coolant channels 126 circulating cooling to the faceplate 104, bullnoses 122, and the noses 106a of the POMs 106 and the cold plates 114 circulating coolant to the bodies 106b of the POMs 106. As is illustrated, an upper coolant channel 126 may be provided to cool the faceplate 104 adjacent to the noses 106a of an upper row of POMs 106, with upper riding cold plates 114 used to cool the bodies 106b of the upper row of POMs 106. A lower coolant channel 126 may be provided to cool the faceplate 104 adjacent to the noses 106a of a lower row of POMs 106, with lower riding cold plates 114 used to cool the bodies 106b of the lower row of POMs 106.

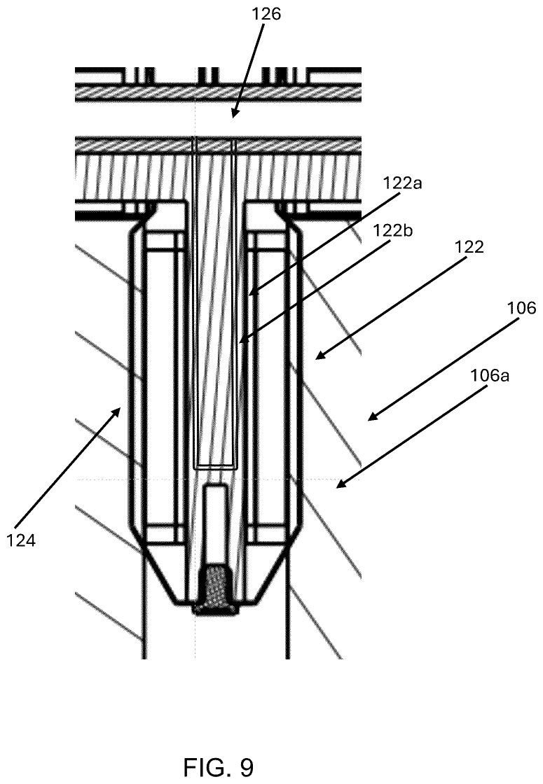

Referring to FIG. 9, an alternative configuration of the bullnoses 122 is shown. Again, each of the coolant channels 126 runs adjacent to the internal surface of the faceplate 104, or through the faceplate 104, from the inlet 126a to the outlet 126b between the noses 106a of the associated POMs 106 and the associated cold plates 114 disposed in the housing 102. Both the coolant channels 126 and the cold plates 114 are coupled to the liquid cooling system 112 of the module or element 100, the coolant channels 126 circulating cooling to the faceplate 104, bullnoses 122, and the noses 106a of the POMs 106 and the cold plates 114 circulating coolant to the bodies 106b of the POMs 106. Each of the bullnoses 122 again includes a wall structure 122a made of a high conductivity metallic material or the like that is integrally formed with or is coupled to and protrudes from the external surface of the faceplate 104. The GOF pads 124 that thermally contact the sides of the noses 106a of the POMs 106 are coupled to the sides of the wall structure 122a. Here, a bullnose coolant channel 122b is fluidly coupled to the coolant channel 126 and circulates coolant through each of the wall structures 122a of the bullnoses 122, adjacent to the GOF pads 124. This further enhances cooling of the noses 106a of the POMs 106.

In some embodiments, the present disclosure is generalized to cool a device 106 that is disposed adjacent to an internal surface of the faceplate 104, such as a device 106 disposed on the PCB 116 within the housing 102, but that does not protrude through the faceplate 104. The coolant channel 126 is again coupled to an internal surface of the faceplate 104 or formed through the faceplate body 104a adjacent to the device 106 when the device 106 is disposed adjacent to the faceplate body 104a and thermally coupled to the faceplate body 104a. A bullnose 122, and likely multiple bullnoses 122, each including a wall structure 122a is/are integrally formed with or coupled to the internal surface of the faceplate body 104a and disposed adjacent and thermally coupled to a side of the device 106 when the device is disposed adjacent to the faceplate body 104a. Again, in some embodiments, the wall structure 122a defines a bullnose coolant channel 122b that is fluidly coupled to the coolant channel 126. In some embodiments, the bullnose further includes a GOF pad 124 coupled to the wall structure 122a and adapted to thermally couple the bullnose 122 to the side of the device 106.

The following configuration was simulated to verify the operation of the liquid cooled faceplate 104 of the present disclosure:
QSFP-DD POM of similar construction to a 400ZR/400ZR+ or 800ZR plug, but with a 38 W DSP and an 8 W ITLA for a total POM power of approximately 55 W
40° C. coolant temperature
40° C. air temperature
Copper faceplate
Copper bullnoses positioned adjacent to left and right sides of the POM nose
GOF pads used as bridges between the POM nose and the bullnoses
Thermal contact resistance between the POM case top and a main cold plate pedestal: 2° C.·cm²/W
Faceplate coolant: water
Faceplate coolant flowrate: 0.6 L/s
Faceplate coolant channel cross section area: 9 mm²
Vertical envelope: two POMs belly-to-belly in 1 U

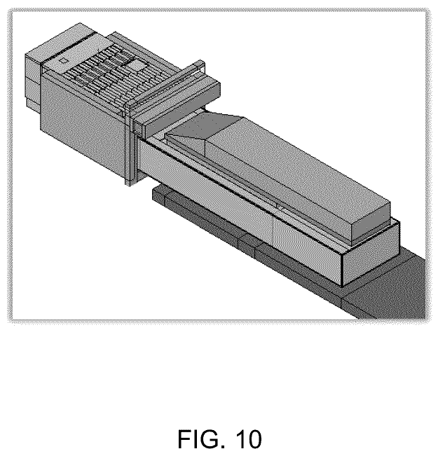

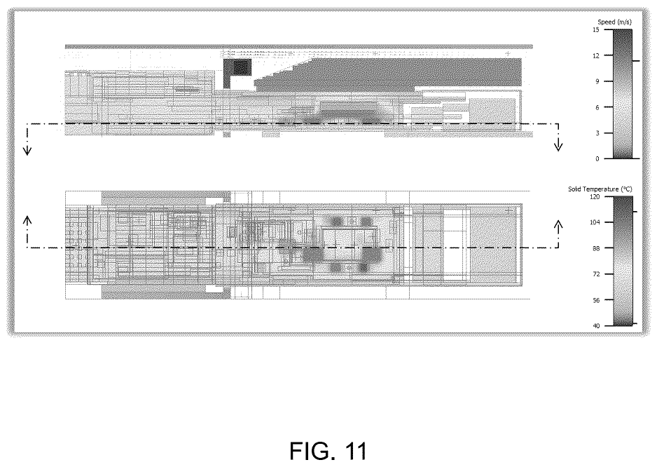

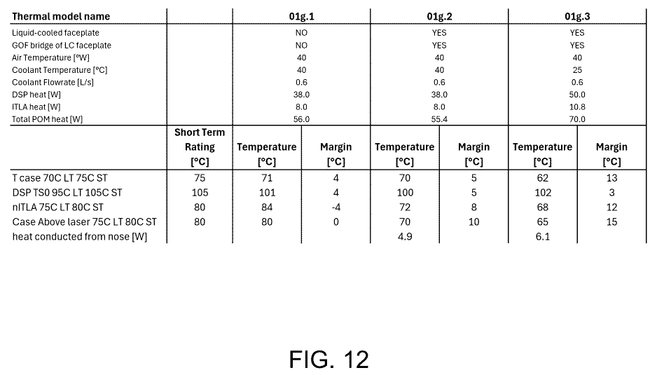

FIG. 10 shows the POM thermal model and FIG. 11 shows the solved model with plotted temperatures and flow vectors. It is apparent from FIG. 11 that the bullnose features that extend forward from the faceplate serve as effective cold sinks, several ° C. cooler than the POM nose. FIG. 12 shows the numerical values associated with three thermal models: 1) a thermal model of the POM that does not use nose cooling in a liquid cooled faceplate, which serves as a reference model for comparison—this model included an 8 W ITLA which exceeds its max temperature rating by 4° C.; 2) the thermal model described previously, including POM nose cooling in a liquid cooled faceplate cooled by 40° C. coolant—of note is how the 8 W ITLA drops in temperature by 12° C. relative to the reference design thanks primarily to the 4.9 W dissipated by the POM nose into the liquid cooled faceplate—the ITLA is no longer a system-limiting component; and 3) a thermal model similar to the thermal model described previously, but with a coolant temperature of 25° C. (i.e., more effective cold sinks), and increased DSP and ITLA power—this simulation suggests that a 70 W POM may be sufficiently cooled when applying liquid cooling as described, far exceeding the max POM power that was previously thought to be coolable.

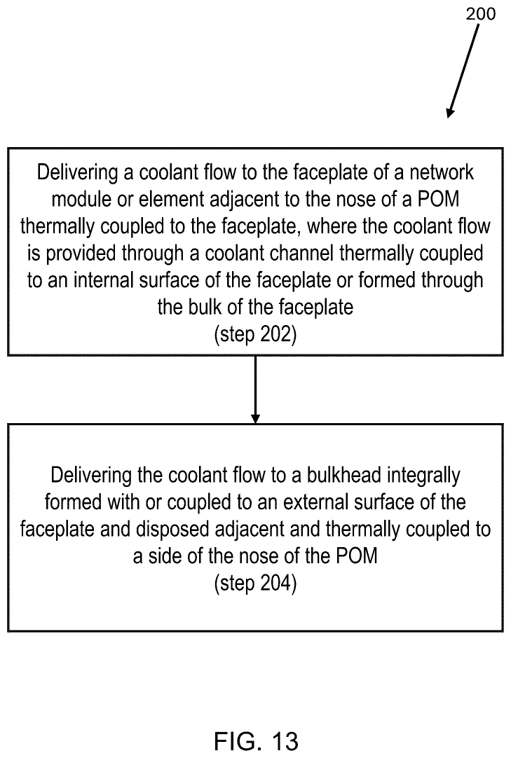

Referring to FIG. 13, the faceplate liquid cooling method 200 of the present disclosure fundamentally includes delivering a coolant flow to the faceplate of a network module or element adjacent to the nose of a POM thermally coupled to the faceplate, where the coolant flow is provided through a coolant channel thermally coupled to an internal surface of the faceplate or formed through the bulk of the faceplate (step 202). Optionally, the method also includes delivering the coolant flow to a bullnose integrally formed with or coupled to an external surface of the faceplate and disposed adjacent and thermally coupled to a side of the nose of the POM (step 204).

Thus, the present disclosure provides heat exchange surfaces in a faceplate which transfer heat into a working coolant. The faceplate geometry and the faceplate material selection together serve to bring heat from the heat source to the solid-to-coolant heat exchange surfaces in a manner of low thermal resistance. A thermally conductive bridge is provided between the POM and the liquid cooled faceplate, and the thermally conductive bridge is provided with elasticity or viscoelasticity. This thermally conductive bridge is provided between motherboard devices and the liquid cooled faceplate. The branches of the coolant piping network of the network module or element supply cold side coolant to the faceplate and to return heated side coolant from the faceplate, providing a method of removing heat from the faceplate by means of liquid cooling.

Conventionally, a POM is primarily cooled by a cold plate that makes sprung contact with the case top of the POM. In an air cooled system, the cold plate is typically a parallel plate heat sink or pin-fin heat sink. In a liquid cooled system, the cold plate is a liquid cooled cold plate. A POM is also cooled, in part, directly by air flow (convection) across other available surfaces of the POM; e.g., sides, bottom, and nose surfaces. Such cooling is possibly enhanced by including cuts and openings in the POM body, the POM cage, and/or the adjacent PCB. A POM may also be cooled, in part, by a cold plate that makes sprung contact with the case bottom of the POM. A POM may further be cooled, in part, by conducting heat through an elastic and thermally conductive bridge between one or more surfaces of the POM nose to features on the faceplate. This is effective only so long as the system is designed to liberate sufficient heat from the faceplate into the environment.

Using the known solutions, the maximum POM power that can be dissipated is limited in great part by the net thermal resistance between POM case and ambient and coolant temperatures. In an air cooled system, the practical limit is approximately 30-40 W. In a liquid cooled system, the practical limit is approximately 50 W. These values are approximate, and depend significantly on system implementation, as well as the operating ambient, which is assumed to be approximately 40° C. air in air cooled systems and 40° C. coolant in liquid cooled systems. Using the best of the known solutions, simulations suggest that components in the nose of the POM are those that thermally limit the POM, and likely thermally limit the entire server/networking/switching product. For example, when using a liquid cooled riding cold plate on a 50 W QSFP-DD, the ITLA (in the nose) overheats, while the next hottest components (CDM driver and DSP) are sufficiently cooled.

The shortcoming that is addressed by the present disclosure is the lack of effective dissipation of the heat that is generated in the nose of a high power POM. Two parameters affect the effectiveness of cooling from the nose surfaces: 1) the thermal resistance between the nose surfaces and some adjacent cold sink and 2) the temperature of the adjacent cold sink. The first is addressed by a thermal conductive elastic bridge between the nose and the cold sink. One implementation is to use the GOF pad as the bridge. The present disclosure addresses the second—the temperature of the cold sink. The faceplate is used as the cold sink, and heat conducted to the faceplate is dissipated into the coolant of the liquid cooled sub-system. The use of liquid cooling to cool the faceplate is a highly effective means to keep the faceplate (cold sink) at a relatively low temperature. Using this method, it is even possible to keep the faceplate colder than ambient air to further improve the usefulness of the faceplate (cold sink).

The operating principles, in order of heat transfer from source to coolant, include:
Heat generated in the nose of the POM (for example, by the ITLA) has multiple thermal paths away from the nose; i.e., towards the distant case top cold plate, towards the nearest nose surfaces, etc. The thermal bridge from the nose to the cold faceplate serves to create a preferred heat path of much lower thermal resistance than that which can be achieved by air cooling the same surfaces.
The thermal bridge is made of a low friction thermally conductive and elastic material (or sub-assembly). The thickness of the bridge is sized such that the POM nose somewhat compresses the bridge when the POM is inserted. This results in the bridge being somewhat compressed. The low friction aspect allows for a POM to be inserted or retracted (possibly multiple times) with reasonably low force. The compressibility and elasticity ensures that the there is always good thermal contact between the POM nose surface and the adjacent bridge, as well as contact between the bridge and the adjacent faceplate.
The thermal bridge is in contact with the faceplate via the faceplate bullnose. The bullnose is thermally conductive (likely the same stock material as the main body of the faceplate). It is constructed with a sufficient robustness to provide a stiff reference surface against the compressed bridge. It is constructed with sufficient solid cross-section to minimize the thermal resistance between the bridge and the coolant, which may be on the order of centimeters away. Heat is thus effectively transferred from the bridge contact area toward the coolant.
The faceplate is cooled by coolant similar to the manner in which a liquid cooled CPU cold plate is cooled by coolant. One implementation is to solder, braze, or glue the thermally conductive coolant channel (e.g., Cu tube) into a channel cut into the faceplate of similar cross-section. At the end points of the coolant channel are features to connect it to the coolant sub-system. Various parameters of the coolant channel within the faceplate are chosen for the coolant to effectively keep the faceplate cool against the many Watts of heat that it draws from the nose of the POM(s). Such parameters of the coolant channel are: coolant type, coolant supply temperature, coolant flow rate, heat removed from POM nose, total number of POM noses cooled, cross-section dimensions of the coolant channel, and presence of fins or protrusions within the coolant channel.

Although the present disclosure is illustrated and described with reference to specific embodiments and examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A liquid cooled faceplate assembly for cooling a pluggable optical module, the liquid cooled faceplate assembly comprising
a faceplate body, and
a coolant channel coupled to a surface of the faceplate body or formed through the faceplate body adjacent to a nose of the pluggable optical module when the pluggable optical module is inserted through an opening formed in the faceplate body and thermally coupled to the faceplate body.

2. The liquid cooled faceplate assembly of claim 1, further comprising a bullnose comprising a wall structure integrally formed with or coupled to an the surface or another surface of the faceplate body and disposed adjacent and thermally coupled to a side of the nose of the pluggable optical module when the pluggable optical module is inserted through the opening formed in the faceplate body.

3. The liquid cooled faceplate assembly of claim 2, wherein the wall structure defines a bullnose coolant channel that is fluidly coupled to the coolant channel.

4. The liquid cooled faceplate assembly of claim 2, wherein the bullnose further comprises a graphite-over-foam pad coupled to the wall structure and adapted to thermally couple the bullnose to the side of the nose of the pluggable optical module.

5. The liquid cooled faceplate assembly of claim 1, wherein the coolant channel comprises a coolant inlet and a coolant outlet adapted to be fluidly coupled to a liquid cooling system of a network module or element.

6. The liquid cooled faceplate assembly of claim 1, wherein the coolant channel comprises or defines internal fins or protrusions acting as internal fins or protrusions acting as internal heat transfer features.

7. The liquid cooled faceplate assembly of claim 1, wherein the coolant channel comprises an upper coolant channel coupled to the surface of the faceplate body or formed through the faceplate body adjacent to noses of a row of upper pluggable optical modules when the upper pluggable optical modules are inserted through an upper row of openings formed in the faceplate body and thermally coupled to the faceplate body and a lower coolant channel coupled to the surface of the faceplate body or formed through the faceplate body adjacent to noses of a row of lower pluggable optical modules when the lower pluggable optical modules are inserted through a lower row of openings formed in the faceplate body and thermally coupled to the faceplate body.

8. The liquid cooled faceplate assembly of claim 2, wherein the bullnose comprises a plurality of bullnoses each comprising the wall structure integrally formed with or coupled to the surface or the other surface of the faceplate body and disposed adjacent and thermally coupled to sides of noses of a row of pluggable optical modules when the pluggable optical modules are inserted through a row of openings formed in the faceplate body.

9. The liquid cooled faceplate assembly of claim 1, wherein the coolant channel is disposed between the nose of the pluggable optical module and a cold plate disposed adjacent and thermally coupled to a body of the pluggable optical module when the pluggable optical module is inserted through the opening formed in the faceplate body, wherein the cold plate is disposed within a housing to which the faceplate body is attached.

10. A network element comprising
a housing,
a pluggable optical module having a body disposed within the housing and a nose extending from the housing, and
a liquid cooled faceplate assembly for cooling the pluggable optical module, the liquid cooled faceplate assembly comprising
a faceplate body, and
a coolant channel coupled to a surface of the faceplate body or formed through the faceplate body adjacent to the nose of the pluggable optical module when the pluggable optical module is inserted through an opening formed in the faceplate body and thermally coupled to the faceplate body.

11. The network element of claim 10, wherein the liquid cooled faceplate assembly further comprises a bullnose comprising a wall structure integrally formed with or coupled to the surface or another surface of the faceplate body and disposed adjacent and thermally coupled to a side of the nose of the pluggable optical module when the pluggable optical module is inserted through the opening formed in the faceplate body.

12. The network element of claim 11, wherein the wall structure defines a bullnose coolant channel that is fluidly coupled to the coolant channel.

13. The network element of claim 10, wherein the bullnose further comprises a graphite-over-foam pad coupled to the wall structure and adapted to thermally couple the bullnose to the side of the nose of the pluggable optical module.

14. The network element of claim 10, wherein the coolant channel comprises a coolant inlet and a coolant outlet adapted to be fluidly coupled to a liquid cooling system of a network module or element.

15. The network element of claim 10, wherein the coolant channel comprises or defines internal fins or protrusions acting as internal heat transfer features.

16. The network element of claim 10, wherein the pluggable optical module comprises a row of upper pluggable optical modules and a row of lower pluggable optical modules, and wherein the coolant channel comprises an upper coolant channel coupled to the surface of the faceplate body or formed through the faceplate body adjacent to noses of the row of upper pluggable optical modules when the upper pluggable optical modules are inserted through an upper row of openings formed in the faceplate body and thermally coupled to the faceplate body and a lower coolant channel coupled to the surface of the faceplate body or formed through the faceplate body adjacent to noses of the row of lower pluggable optical modules when the lower pluggable optical modules are inserted through a lower row of openings formed in the faceplate body and thermally coupled to the faceplate body.

17. The network element of claim 11, wherein the pluggable optical module comprises a row of pluggable optical modules, and wherein the bullnose comprises a plurality of bullnoses each comprising the wall structure integrally formed with or coupled to the surface or the other surface of the faceplate body and disposed adjacent and thermally coupled to sides of noses of a row of pluggable optical modules when the pluggable optical modules are inserted through a row of openings formed in the faceplate body.

18. The network element of claim 10, wherein the coolant channel is disposed between the nose of the pluggable optical module and a cold plate disposed adjacent and thermally coupled to a body of the pluggable optical module when the pluggable optical module is inserted through the opening formed in the faceplate body, wherein the cold plate is disposed within the housing to which the faceplate body is attached.

19. A liquid cooled faceplate assembly for cooling a device, the liquid cooled faceplate assembly comprising
a faceplate body, and
a coolant channel coupled to a surface of the faceplate body or formed through the faceplate body adjacent to the device when the device is disposed adjacent to the faceplate body and thermally coupled to the faceplate body.

20. The liquid cooled faceplate assembly of claim 19, further comprising a bullnose comprising a wall structure integrally formed with or coupled to the surface or another surface of the faceplate body and disposed adjacent and thermally coupled to a side of the device when the device is disposed adjacent to the faceplate body.
